(19) United States
(12) Patent Application Publication
(10) Pub. No.: US 2010/0155961 A1
(43) Pub. Date: Jun. 24, 2010

(54) MICROMECHANICAL COMPONENT HAVING WAFER THROUGH-PLATING AND CORRESPONDING PRODUCTION METHOD

(76) Inventor: Ando Feyh, Tamm (DE)

Correspondence Address: KENYON & KENYON LLP, ONE BROADWAY, NEW YORK, NY, 10004, US

(21) Appl. No.: 12/296,128

(22) PCT Filed: Mar. 21, 2007
(86) PCT No.: PCT/EP07/52700

§ 371 Date: Oct. 6, 2008

(30) Foreign Application Priority Data
Apr. 19, 2006 (DE) 10 2006 018 027.5

(51) Int. Cl. H01L 23/48; H01L 21/768

(52) U.S. Cl. 257/774; 438/667; 257/E21.597; 257/E23.011

(57) ABSTRACT

A wafer through-plating through a semiconductor substrate and a method for producing this wafer through-plating. At least one via hole is inserted in the front side of a semiconductor substrate, in this context, in order to form the wafer through-plating using a trench etching process. The semiconductor material of the side wall of the via hole is then porously etched in an electrochemical etching process. A metal is introduced into the via hole in order to produce the electrical contact-making connection. In order to enable the electrical connection from the front side to the back side of the semiconductor substrate, the via hole is opened from the back side, for example, by thinning the semiconductor substrate. This opening may be made, in this context, before or after the metal is introduced into the via hole.

### FIELD OF THE INVENTION

The present invention relates to a method for producing at least one wafer through-plating through a semiconductor substrate, for the formation of the wafer through-plating.

### BACKGROUND INFORMATION

Up to now, wafer through-platings (vias) have been electrically insulated from the substrate using dielectric layers. For this purpose, vias are coated with oxides/nitrides using thermal oxidation or LPCVD processes. High temperatures are usually required for such coatings. Thus, temperatures of typically 900-1100° C. are reached during the (bulk) oxidation. These high temperatures may lead to damage of structures of the sensor elements made before on the substrate or of evaluation circuits in the form of ASICs.

If processes are used for the electrical insulation of the wafer through-platings which are able to make do without such a thermal load of the structures or circuits already generated, for instance, within the scope of PECVD processes, a conformal and depthwise homogeneous coating of the vias cannot be assured. Consequently, in the case of deep vias, an insulation property cannot be achieved in a controlled manner.

The production of such a contacting is discussed in German patent document DE 100 58 864 A1. This document discusses a contact hole that is etched perpendicularly into layers applied on a substrate. The contact hole is subsequently filled up with an electrically conductive material or a metal, and is used for the electrical connection of buried pads or contact areas.

Another possibility in the production of contact holes is discussed in DE 100 42 945 A1. In this document, a cavity is generated having column-like supportive structures inside a component. Contact holes are etched into the supportive structures for the formation of electric lines which are subsequently filled up with tungsten.

In the case of massive metallic vias, high tensions may develop based on the different thermal coefficients of expansion between the metal and the semiconductor material directly surrounding the metal, and this can result in breakage of the vias during operation.

### SUMMARY OF THE INVENTION

Therefore it is an object of the exemplary embodiments and/or exemplary methods of the present invention to provide a method for insulating wafer through-platings, while avoiding a high temperature input into the substrate, which demonstrate good thermal and electrical insulation properties, in conjunction with stress alleviation of the metallic vias by the substrate.

The exemplary embodiments and/or exemplary methods of the present invention describes a wafer through-plating through a semiconductor substrate and a production method for this wafer through-plating. At least one via hole is applied in the front side of a semiconductor substrate, in this context, for the formation of the wafer through-plating using a trench etching process. The semiconductor material of the side wall of the via hole is subsequently etched porous in an electrochemical etching process. A metal is applied in the via hole to produce the electrical connection of the contacting. In order to enable the electrical connection from the front side to the back side of the semiconductor substrate, the via hole is opened from the back side, for instance, by thinning the semiconductor substrate. The opening may be performed, in this instance, before or after the application of the metal into the via hole.

By the production of such a wafer through-plating (via), the electrical line, which is generated by the metallization in the via hole, is able to be insulated electrically and thermally, both from the surrounding semiconductor substrate and from additional vias. In addition, using a porous structure is able to absorb stresses caused by thermal loads. Furthermore, because of the aspect ratios used in the trench etching process, a depthwise homogeneous insulation property may be achieved over the full length of the via. In contrast to an insulation of the side walls using thermal oxidation or LPCVD deposition, the thermal load of the semiconductor substrate is able to be held low in this manner.

The metallization of the vias is advantageously produced using a galvanic system.

It is further provided that one should thermally oxidize the porous layer at the side wall of the via hole, particularly low temperatures of ca. 300-400° C. being provided.

In one refinement of the exemplary embodiments and/or exemplary methods of the present invention, the porosity of the side wall may be varied, for example, in that the porosity increases, starting from the side wall, and going into the substrate. The intensity of the thermal insulation is able to be adjusted thereby. Furthermore, it is conceivable that the pores of the side wall have a pore size of less than 5 nm.

In one special embodiment of the exemplary embodiments and/or exemplary methods of the present invention, it is provided that a sensor element be applied onto the front side and/or the back side of the semiconductor substrate. It may be provided in this context that the sensor element is produced directly in the semiconductor substrate or is applied as an additional component. The wafer through-plating is provided, in this context, as the electrical connection of the sensor element and as the continuation of the electrical contact to the side facing away from the sensor element of the semiconductor substrate. Alternatively or in supplementation, however, an evaluation circuit may also be provided instead of a sensor element. The circuit may also be applied, in this instance, in the semiconductor substrate, or, in the form of an additional component, on the semiconductor substrate.

Further advantages result from the following description of exemplary embodiments, and from the dependent patent claims.

### BRIEF DESCRIPTION OF THE DRAWINGS

FIG. 1 shows a production operation of a wafer through-plating according to the present invention, in exemplary fashion.

FIG. 2 shows another production operation of a wafer through-plating according to the present invention, in exemplary fashion.

FIG. 3 shows another production operation of a wafer through-plating according to the present invention, in exemplary fashion.

FIG. 4 shows another production operation of a wafer through-plating according to the present invention, in exemplary fashion.

FIG. 5 shows another production operation of a wafer through-plating according to the present invention, in exemplary fashion.

FIG. 6 shows another production operation of a wafer through-plating according to the present invention, in exemplary fashion.

FIG. 7 shows another production operation of a wafer through-plating according to the present invention, in exemplary fashion.

FIG. 8 shows another production operation of a wafer through-plating according to the present invention, in exemplary fashion.

FIG. 9 shows an exemplary embodiment, which shows the connection of a sensor element and an (evaluation) circuit using the wafer through-plating.

### DETAILED DESCRIPTION

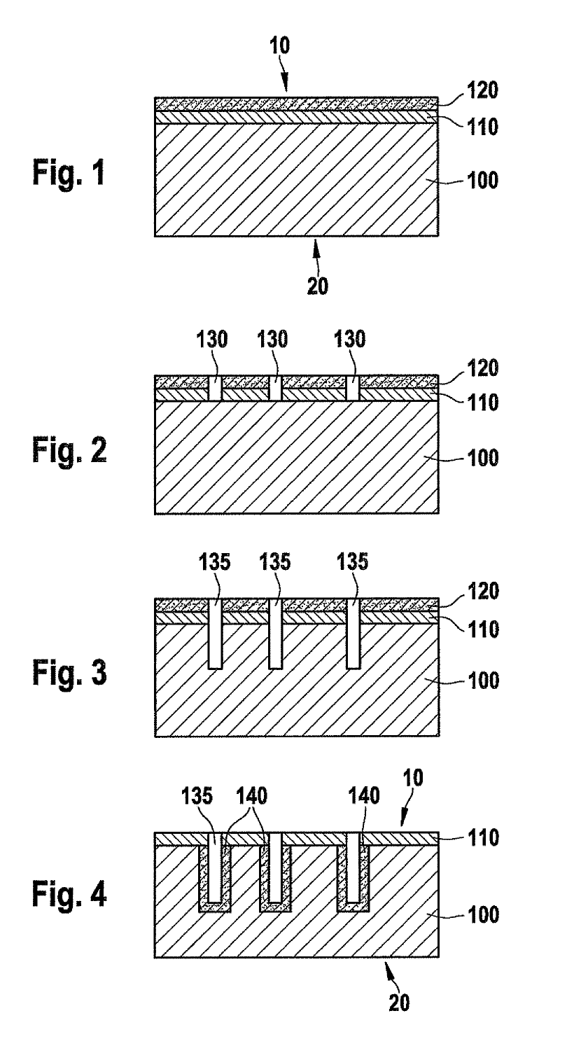

As shown in FIG. 1, first a masking layer 110, for instance, of SiN, Si₃N₄ or an n-doped zone of the silicon substrate is applied onto surface 10 of a silicon substrate 100, to produce the porous silicon, and a second masking layer 120 of oxide or photoresist is applied for the subsequent trench etching step. Silicon wafers may be used in micromechanical components, wafers made of other semiconductor materials finding application equally well.

In a first process step, using suitable patterning, holes 130 are inserted into first and second masking layers 110 and 120, through which the trench etching step will be carried out in the subsequent process step. One or more (deep) via holes 135 are generated in the silicon substrate 100 using this trench etching step. Subsequently, second masking 120 is removed, as may be seen in FIG. 4. The silicon of the side walls of the via holes is then porously etched, using an electrochemical etching process, the first masking layer 110 preventing the etching of surface 10 of the silicon substrate. The extension of thus generated porous region 140 in silicon substrate 100 is dependent, in this instance, of the etching parameters used, such as acid strength, current strength applied and etching time. A hydrofluoric acid-containing electrolyte such as HF is suitable as the etching medium, other media also being able to be used that have a porosifying effect on the semiconductor material used.

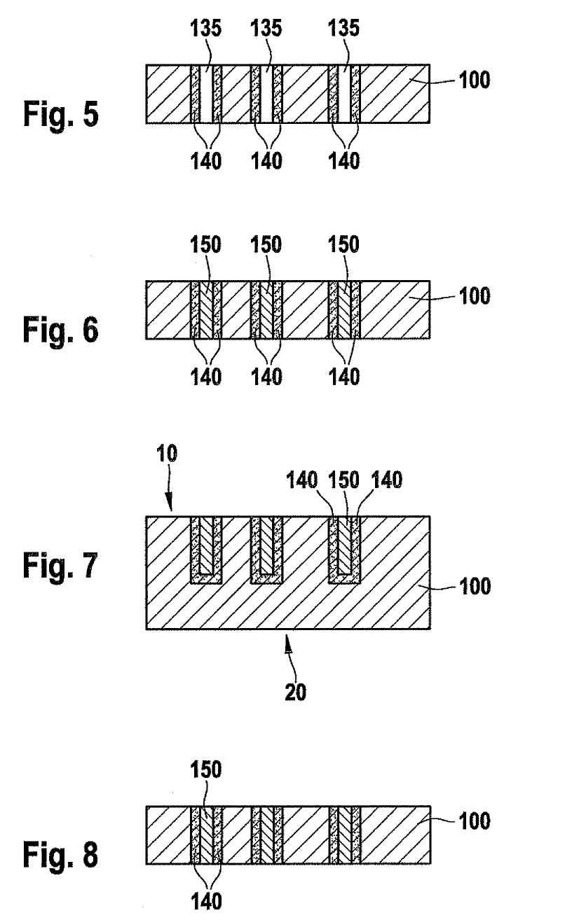

Starting from FIG. 4, it is first shown, using an exemplary embodiment, that after the production of via holes 135 having porous side walls 140, semiconductor substrate 100 is thinned from the direction of the back side (see FIG. 5) before the via holes 150 are filled up, using metallization, such as a galvanic process (see FIG. 6). Alternatively it my also be provided that via holes 150 are first filled with the metallization, before via holes 150 are opened from the back side 20 of semiconductor substrate 100 (see FIGS. 7 and 8).

By suitable control of the etching parameters, besides the thickness of the porosified layer, one is also able to set the pore size. Nonporous silicon having a pore size of less than 5 nm may be produced in this instance, for example. Furthermore, the porosity gradient may be varied during the porosification. In this connection, low-porosity layers are conceivable at the surface of the side wall, and high-porosity layers going towards the substrate. This would have adhering advantages of additionally deposited layers and with respect to the subsequent metallization. At the same time, such a porosity gradient would generate an additional increase in insulation.

Alternatively, it is also possible to oxidize the porous layer at low temperatures, that is, at 300-400° C. By doing this, the insulation effect could also be improved. In response to a suitable selection of the porosity, a closed oxidation surface may be generated after oxidation, based on the growth in volume of the oxidized porous silicon, without having to use correspondingly high temperatures which would otherwise be required for a bulk oxidation.

The wafer through-plating according to the exemplary embodiments and/or exemplary methods of the present invention may be used, for instance, in the production of a micromechanical sensor element. It is thus conceivable that, on the silicon substrate, micromechanical structures for a sensor element are produced, such as an acceleration sensor, a yaw rate sensor, an air mass sensor or a pressure sensor, which are electrically connected and activated using the wafer through-plating. It is advantageous, in this context, that the electrical activation is able to be guided all the way through the substrate to the other side of the substrate. It may also be optionally provided that on the other side of the substrate circuit elements have already been provided which perform a pickup or an evaluation of the sensor measuring values. The advantage in such conductor arrangements is that, on the surface of the sensor element, less space is required for conducting away and evaluating the measuring signals.

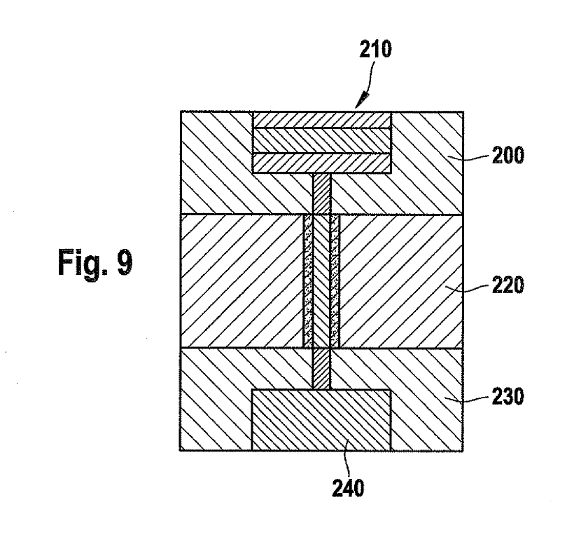

An additional application of the wafer through-plating, according to the exemplary embodiments and/or exemplary methods of the present invention, is to connect to one another mechanically and electrically, that is to contact one or two separate components which, on their part, already have finished processed sensor elements or circuits. As a possible example, we refer to FIG. 9, in which a sensor element 200 is connected to an evaluation chip 230 via a component 220 that is equipped with a wafer through-plating. In this context, the measuring signal of a capacitive pressure sensor 210 is conducted on downwards using an upper and a lower electrode (in the example, the lower electrode is connected), and is conducted on for evaluation to an evaluating chip 230 that is equipped with a corresponding circuit 240.

1-11. (canceled)

12. A method for producing at least one wafer through-plating through a semiconductor substrate, the method comprising:
inserting at least one via hole into a front side of a semiconductor substrate using a trench etching process;
etching porous a side wall of the at least one via hole using an electrochemical etching process;
filling up the via hole using a metallization; and
opening the via hole from a back side of the semiconductor substrate.

13. The method of claim 12, wherein the metallization is performed using a galvanic system.

14. The method of claim 12, wherein the metallization is performed after the opening of the via hole.

15. The method of claim 12, wherein the opening of the at least one via hole is performed from the back side, using a back thinning of the semiconductor substrate.

16. The method of claim 12, wherein the porous layer is thermally oxidized at the side wall, the thermal oxidation being performed at temperatures of 300-400° C.

17. The method of claim 12, wherein the wafer through-plating is produced after the production of at least one of a sensor element and an evaluation circuit on one of a front side and a back side of the semiconductor substrate, and has an electrical connection to the at least one of the sensor element and the evaluation circuit.

18. A micromechanical component comprising:
a semiconductor substrate having a wafer through-plating having a via hole inserted by a trench etching process into the semiconductor substrate from the front side, the via hole having a side wall of porously etched semiconductor material, a metallization, and an opening to a back side of the semiconductor substrate;
wherein the at least one wafer through-plating through a semiconductor substrate is produced by performing the following:
inserting at least one via hole into a front side of a semiconductor substrate using a trench etching process;
etching porous a side wall of the at least one via hole using an electrochemical etching process;
filling up the via hole using a metallization; and
opening the via hole from the back side of the semiconductor substrate.

19. The micromechanical component of claim 18, wherein the porosity increases starting from the side wall of the via hole and going all the way into the substrate.

20. The micromechanical component of claim 18, wherein the pores have a pore size of less than 5 nm.

21. The micromechanical component of claim 18, wherein the semiconductor substrate has at least one of a sensor element and an evaluation circuit on one of a front side and a back side of the semiconductor substrate and the wafer through-plating has an electrical connection to the at least one of the sensor element and the evaluation circuit.

22. The micromechanical component of claim 18, wherein a component having at least one of a sensor element and an evaluation circuit is applied onto the semiconductor substrate, and the wafer through-plating in the semiconductor substrate has an electrical connection to the at least one of the sensor element and the evaluation circuit.
